(19) United States
(12) Patent Application Publication
(10) Pub. No.: US 2025/0336828 A1
(43) Pub. Date: Oct. 30, 2025

(54) SEMICONDUCTOR DEVICES, FORMATION METHODS THEREOF AND MEMORY SYSTEMS

(71) Applicant: Yangtze Memory Technologies Co., Ltd., Wuhan (CN)

(72) Inventors: Zheng XIANG, Wuhan (CN); Pan HUANG, Wuhan (CN); Jin PENG, Wuhan (CN); Houxiao WU, Wuhan (CN); Yichong LIU, Wuhan (CN)

(21) Appl. No.: 18/892,231

(22) Filed: Sep. 20, 2024

(30) Foreign Application Priority Data
Apr. 29, 2024 (CN) 202410534453.6

(51) Int. Cl. H01L 23/535; H01L 21/768; H01L 23/528; H01L 23/532

(52) U.S. Cl. CPC H01L 23/535; H01L 21/76805; H01L 21/7682; H01L 21/76895; H01L 23/5283; H01L 23/5329

(57) ABSTRACT

The present disclosure provides semiconductor devices, formation methods thereof, and memory systems. The semiconductor device includes: conductive lines extending along a first direction and spaced apart along a second direction, wherein the first direction intersects the second direction; and a contact structure extending along a third direction and at least connected to a first conductive line of the conductive lines, wherein the contact structure includes a first contact sub-structure connected with the first conductive line and a second contact sub-structure on the first contact sub-structure; in the second direction, a first dimension of the first contact sub-structure at a boundary between the first contact sub-structure and second contact sub-structure is smaller than a second dimension of the second contact sub-structure at the boundary between the first contact sub-structure and second contact sub-structure, wherein the third direction is perpendicular to both the first direction and second direction.

### CROSS-REFERENCE TO RELATED APPLICATIONS

This application claims priority to Chinese Patent Application No. 202410534453.6, filed on Apr. 29, 2024, which is hereby incorporated by reference in its entirety.

### TECHNICAL FIELD

Examples of the present disclosure relate to the field of semiconductor technology, and relate to, but are not limited to, a semiconductor device, a formation method thereof, and a memory system.

### BACKGROUND

With the rapid development of semiconductor manufacturing technologies, semiconductor devices are developing towards a higher component density and integration level. However, with an increase in density and decrease in sizes of the semiconductor devices, the manufacturing process of the semiconductor devices becomes more challenging, thereby leading to performance degradation of the manufactured semiconductor devices.

### SUMMARY

In view of this, examples of the present disclosure provide a semiconductor device, a formation method thereof, and a memory system.

According to a first aspect of the examples of the present disclosure, a semiconductor device is provided, comprising: a plurality of conductive lines extending along a first direction and spaced apart along a second direction, wherein the first direction intersects the second direction; and a contact structure extending along a third direction and at least connected to a first conductive line of the plurality of conductive lines, wherein the contact structure comprises a first contact sub-structure connected with the first conductive line and a second contact sub-structure located on the first contact sub-structure; and in the second direction, a first dimension of the first contact sub-structure at a boundary between the first contact sub-structure and the second contact sub-structure is smaller than a second dimension of the second contact sub-structure at the boundary between the first contact sub-structure and the second contact sub-structure, wherein the third direction is perpendicular to both the first direction and the second direction.

In an implementation, a dimension of the first contact sub-structure along the second direction is the same as a dimension of the first conductive line along the second direction.

In an implementation, in the second direction, a dimension of the first contact sub-structure does not vary along the third direction, and a dimension of the second contact sub-structure varies along the third direction.

In an implementation, in the first direction, a third dimension of the first contact sub-structure at the boundary between the first contact sub-structure and the second contact sub-structure is greater than a fourth dimension of the second contact sub-structure at the boundary between the first contact sub-structure and the second contact sub-structure.

In an implementation, half of a difference between the third dimension and the fourth dimension is greater than a dimension of the first contact sub-structure along the third direction.

In an implementation, a cross section of the second contact sub-structure perpendicular to the third direction comprises any one of a circle, an ellipse or a square.

In an implementation, the semiconductor device further comprises an insulation structure located at a position on the plurality of conductive lines other than a position where the contact structure contacts the first conductive line, wherein a dimension of the insulation structure along the second direction is the same as a dimension of the conductive line along the second direction; and a surface of the insulation structure in contact with the conductive line is flush with a surface of the first contact sub-structure in contact with the first conductive line.

In an implementation, a surface of the insulation structure away from the conductive line is higher than a surface of the first contact sub-structure away from the first conductive line.

In an implementation, in the first direction, half of a difference between a third dimension of the first contact sub-structure at the boundary between the first contact sub-structure and the second contact sub-structure and a fourth dimension of the second contact sub-structure at the boundary between the first contact sub-structure and the second contact sub-structure is the same as a dimension of the insulation structure along the third direction.

In an implementation, a ratio of a dimension of the insulation structure along the third direction to a dimension of the first contact sub-structure along the third direction is in a range of 1.5-5.

In an implementation, a material of the insulation structure includes silicon nitride; and the dimension of the insulation structure along the third direction is in a range of 40 nm-60 nm.

In an implementation, an air gap is disposed between two adjacent conductive lines.

In an implementation, a top surface of the air gap is not higher than top surfaces of the conductive lines.

In an implementation, a ratio of a distance between the adjacent conductive lines to a dimension of the air gap along the second direction is in a range of 1.5-2.5.

In an implementation, a ratio of the second dimension to the first dimension is in a range of 2-5.

In an implementation, the second contact sub-structures of the contact structures on adjacent first conductive lines are staggered in the second direction.

In an implementation, in the second direction, a distance between the second contact sub-structures of the contact structures on the first conductive lines spaced apart is equal to a dimension of the second contact sub-structure.

In an implementation, the dimension of the second contact sub-structure in the second direction is in a range of 8 nm-300 nm.

In an implementation, the conductive line comprises at least one of a bit line, a word line or an interconnect line.

In an implementation, the semiconductor device further comprises a memory array structure and a peripheral structure connected with the memory array structure, wherein the interconnect line is located at a connection of the memory array structure and the peripheral structure.

According to a second aspect of the examples of the present disclosure, a memory system is provided, comprising: at least one semiconductor device of any of the implementations of the first aspect; and a controller configured to control the semiconductor device.

According to a third aspect of the examples of the present disclosure, a formation method of a semiconductor device is provided, comprising: forming a plurality of conductive lines, wherein the plurality of conductive lines extend along a first direction and are spaced apart along a second direction, and the first direction intersects the second direction; and forming a contact structure extending along a third direction and at least connected to a first conductive line of the plurality of conductive lines, wherein the contact structure comprises a first contact sub-structure connected with the first conductive line and a second contact sub-structure located on the first contact sub-structure; and in the second direction, a first dimension of the first contact sub-structure at a boundary between the first contact sub-structure and the second contact sub-structure is smaller than a second dimension of the second contact sub-structure at the boundary between the first contact sub-structure and the second contact sub-structure, wherein the third direction is perpendicular to both the first direction and the second direction.

In an implementation, forming the plurality of conductive lines comprises: forming a conductive material layer and a patterned mask layer sequentially along the third direction, wherein the patterned mask layer comprises an insulation structure in contact with the conductive material layer; removing part of the conductive material layer by using the patterned mask layer, to form the plurality of conductive lines; and removing part of the patterned mask layer except the insulation structure, wherein a dimension of the insulation structure along the second direction is the same as a dimension of the conductive line along the second direction.

In an implementation, forming the contact structure comprises: forming a dielectric layer at least covering the insulation structure; removing part of the dielectric layer and removing part of the insulation structure on the first conductive line to form a contact via; and filling a conductive material in the contact via to form the contact structure connected with the first conductive line.

In an implementation, forming the contact via comprises: removing part of the dielectric layer to form a first via, wherein a bottom of the first via exposes a surface and part of a sidewall of the insulation structure on the first conductive line away from the first conductive line; and a surface of the insulation structure in contact with the conductive line is lower than a bottom surface of the first via; and removing part of the insulation structure on at least the first conductive line along the first via by wet etching to form a second via, wherein a bottom of the second via exposes a top surface of the first conductive line; and the first via and the second via constitute the contact via.

In an implementation, the method further comprises: forming the first vias staggered along the second direction on two adjacent first conductive lines respectively.

In an implementation, in the second direction, a distance between the first vias on the first conductive lines spaced apart is equal to a dimension of the first via.

In an implementation, a dimension of the second via along the second direction is the same as the dimension of the conductive line along the second direction.

In an implementation, in the second direction, a dimension of the second via does not vary along the third direction, and a dimension of the first via varies along the third direction.

In an implementation, in the second direction, a dimension of the second via is smaller than a dimension of the first via.

In an implementation, in the first direction, a dimension of the second via is greater than a dimension of the first via.

In an implementation, in the first direction, half of a difference between the dimension of the second via and the dimension of the first via is equal to a height of the insulation structure along the third direction.

In an implementation, the method further comprises: forming an air gap between two adjacent conductive lines before forming the contact structure on the first conductive line of the plurality of conductive lines.

In an implementation, the insulation structure and the dielectric layer have different etching rates.

In the semiconductor device provided in the examples of the present disclosure, part of the insulation structure on the first conductive line of the conductive lines is removed to reserve a position for forming the first contact sub-structure of the contact structure, and in the second direction, the first dimension of the first contact sub-structure at the boundary between the first contact sub-structure and the second contact sub-structure is smaller than the second dimension of the second contact sub-structure at the boundary between the first contact sub-structure and the second contact sub-structure, such that alignment accuracy between the contact structure and the first conductive line can be effectively improved, contact resistance between the contact structure and the first conductive line is reduced, and overall resistance of the contact structure is reduced. Furthermore, the air gap between the conductive lines can be prevented from damage due to over-etching during the formation of the contact structure, and the performance of the semiconductor device is improved.

### BRIEF DESCRIPTION OF THE DRAWINGS

In the accompanying drawings, unless otherwise specified, identical or similar components or elements are represented by like reference numerals throughout the drawings. These drawings are not necessarily drawn to scale. It is to be understood that, these drawings merely describe some implementations disclosed according to the present disclosure, and should not be considered as limiting the scope of the present disclosure.

FIG. 1 is a schematic cross-sectional view I of main process operations in a process of forming a semiconductor device according to an example of the present disclosure;

FIG. 2 is a schematic cross-sectional view II of main process operations in a process of forming a semiconductor device according to an example of the present disclosure;

FIG. 3 is a flow diagram of implementation of a formation method of a semiconductor device provided by another example of the present disclosure;

FIG. 4 is a schematic cross-sectional view I of a process of a formation method of a semiconductor device provided by another example of the present disclosure;

FIG. 5A is a schematic cross-sectional view II of a process of a formation method of a semiconductor device provided by another example of the present disclosure;

FIG. 5B is a top view corresponding to FIG. 5A;

FIG. 6 is a schematic cross-sectional view III of a process of a formation method of a semiconductor device provided by another example of the present disclosure;

FIG. 6B is a top view corresponding to FIG. 6A;

FIG. 7A is a schematic cross-sectional view IV of a process of a formation method of a semiconductor device provided by another example of the present disclosure;

FIG. 7B is a top view corresponding to FIG. 7A;

FIG. 8A is a schematic cross-sectional view V of a process of a formation method of a semiconductor device provided by another example of the present disclosure;

FIG. 8B is a top view corresponding to FIG. 8A;

FIG. 9A is a schematic cross-sectional view VI of a process of a formation method of a semiconductor device provided by another example of the present disclosure;

FIG. 9B is a schematic cross-sectional view VII corresponding to FIG. 9A;

FIG. 9C is a side view corresponding to FIG. 9A;

FIG. 10A is a schematic cross-sectional view VIII of a process of a formation method of a semiconductor device provided by another example of the present disclosure;

FIG. 10B is an enlarged schematic view of a region A in FIG. 10A;

FIG. 10C is a schematic cross-sectional view IX corresponding to FIG. 10A;

FIG. 10D is an enlarged schematic view of a region B in FIG. 10C;

FIG. 10E is a top view corresponding to FIG. 10A;

FIG. 11 is a schematic view of an example system having a memory system according to an example of the present disclosure;

FIG. 12A is a schematic view of an example memory card having a memory system according to an example of the present application; and

FIG. 12B is a schematic view of an example solid-state drive having a memory system according to an example of the present application.

### DETAILED DESCRIPTION

The technical solutions of the present disclosure will be further described below in detail in conjunction with the drawings and examples. Although the example implementation methods of the present disclosure are shown in the drawings, it is to be understood that the present disclosure may be implemented in various forms and should not be limited by the implementations set forth herein. Rather, these implementations are provided for a more thorough understanding of the present disclosure, and can fully convey the scope of the present disclosure to those skilled in the art.

In the following, the present disclosure is described in more details with reference to the drawings by means of examples. The advantages and features of the present disclosure will be more apparent from the following description. It should be noted that the drawings are all in a very simplified form and have an imprecise scale, only for the purpose of convenient and clear description of examples of the present disclosure.

It should be understood that, spatially relative terms, such as “beneath”, “below”, “lower”, “under”, “over”, “upper”, and the like, may be used herein for ease of description to describe the relationship between one element or feature and other elements or features as illustrated in the figures. It is to be understood that, the spatially relative terms are intended to further encompass different orientations of a device in use or operation in addition to the orientation depicted in the figures. For example, if the device in the drawings is turned over, then the elements or the features described as “below” or “under” or “beneath” other elements may be oriented “on” the other elements or features. Therefore, the example terms “below” and “beneath” may comprise both upper and lower orientations. The device may be orientated otherwise (rotated by 90 degrees or other orientations), and the spatially descriptive terms used herein are interpreted accordingly.

The terms used herein are only intended to describe the specific examples, and are not used as limitations of the present disclosure. As used herein, unless otherwise indicated expressly in the context, “a”, “an” and “the” in a singular form are also intended to comprise a plural form. It should also be understood that terms “consist of” and/or “comprise”, when used in this specification, determine the presence of the described features, integers, steps, operations, elements and/or components, but do not preclude the presence or addition of one or more of other features, integers, steps, operations, elements, components, and/or groups. As used herein, the term “and/or” comprises any or all combinations of the listed relevant items.

It is to be noted that the technical solutions set forth in the examples of the present disclosure may be combined arbitrarily without conflict.

The manufacturing of a semiconductor device need undergo a series of process flows. Traditional process flows may be divided into two main sub-process flows, which are Front End of Line (FEOL) and Back End of Line (BEOL) respectively. The Back End of Line may include a formation process of various conductive interconnect structures (e.g., copper interconnect structures) that are important structures for achieving electrical connection between semiconductor devices. However, since critical dimension (CD) of the semiconductor device is increasingly smaller, defects may easily occur in the formation of the conductive interconnect structure during the Back End of Line, which leads to poor reliability of the semiconductor device, failing to meet requirements.

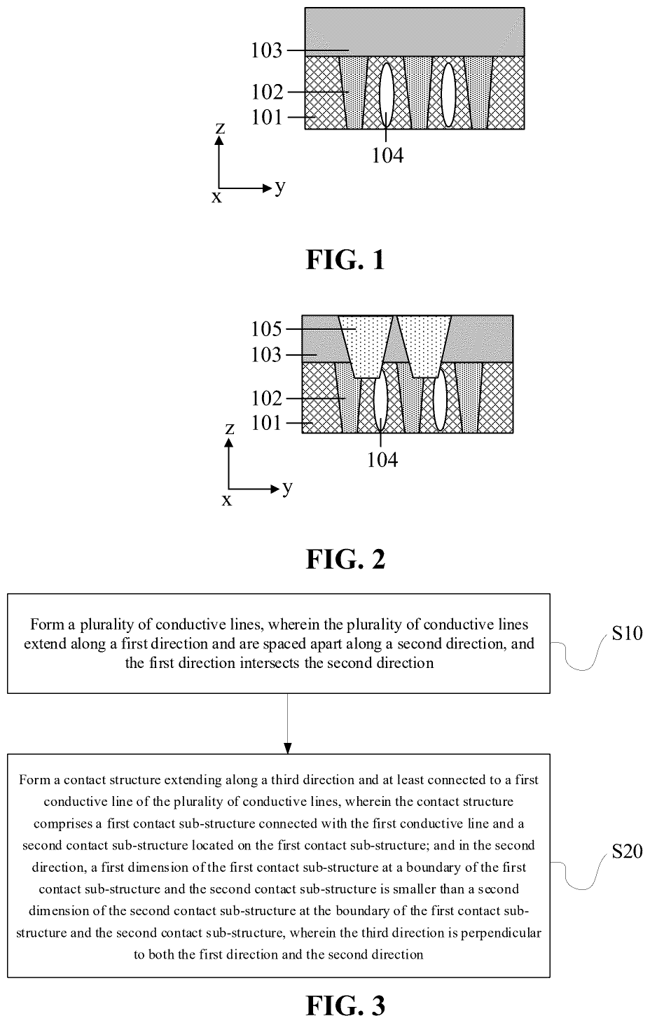

FIGS. 1 and 2 are schematic cross-sectional views of main process operations in a process of forming a semiconductor device according to an example of the present disclosure. A formation method of a semiconductor device of this example is described below in conjunction with FIGS. 1 and 2.

As shown in FIG. 1, a plurality of conductive lines 102 extending along a first direction and spaced apart along a second direction are formed; a first dielectric layer 101 is disposed between the plurality of conductive lines 102; and a second dielectric layer 103 located on the conductive lines 102 and the first dielectric layer 101 is formed.

In some implementations, an air gap 104 is disposed between adjacent ones of the conductive lines 102, and the dielectric constant of air is much lower than the dielectric constant of oxides, such that resistance-capacitance delay (RC Delay) between the conductive lines can be improved.

As shown in FIG. 2, a contact via (not shown in FIG. 2) is formed in the second dielectric layer 103, and a conductive material is filled in the contact via to form a contact structure 105 extending along a third direction.

It is to be noted that, here and below, the first direction may be a direction in which the conductive lines extend, the second direction may be a direction in which the conductive lines are spaced apart, and the third direction may be a direction in which the contact structure extends. The third direction is parallel to a thickness direction of the first dielectric layer, and both the first direction and the second direction are perpendicular to the third direction. The first direction intersects the second direction, and in some examples, the first direction is perpendicular to the second direction. In an example, the first direction may be an extending direction of an x axis shown in the drawings, the second direction may be an extending direction of a y axis shown in the drawings, and the third direction may be an extending direction of a z axis shown in the drawings.

As the critical dimension in the semiconductor process shrinks, etching of the contact via may result in a deviation, i.e., part of the contact via may be etched to the conductive line 102, and another part of the contact via may be etched to the first dielectric layer 103 between the conductive lines 102, thereby damaging the air gap 104 of the first dielectric layer 103 between the conductive lines 102, and affecting the performance of the semiconductor device.

On this basis, examples of the present disclosure provide a formation method of a semiconductor device. FIG. 3 is a flow diagram of implementation of a formation method of a semiconductor device provided by another example of the present disclosure. As shown in FIG. 3, the formation method of the semiconductor device comprises:

S10: forming a plurality of conductive lines, wherein the plurality of conductive lines extend along a first direction and are spaced apart along a second direction, and the first direction intersects the second direction; and

S20: forming a contact structure extending along a third direction and at least connected to a first conductive line of the plurality of conductive lines, wherein the contact structure comprises a first contact sub-structure connected with the first conductive line and a second contact sub-structure located on the first contact sub-structure; and in the second direction, a first dimension of the first contact sub-structure at a boundary between the first contact sub-structure and the second contact sub-structure is smaller than a second dimension of the second contact sub-structure at the boundary between the first contact sub-structure and the second contact sub-structure, wherein the third direction is perpendicular to both the first direction and the second direction.

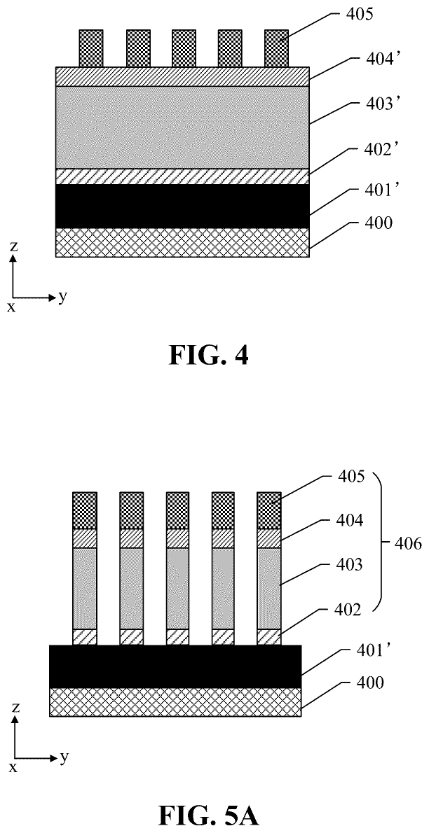

Next, with reference to FIGS. 4 to 10E, the process of the formation method of the semiconductor device provided by another example of the present disclosure is further described in detail.

With reference to FIGS. 4 to 6B, S10 is performed to form the plurality of conductive lines.

As shown in FIG. 4, a base 400 is provided. A conductive material layer 401′, an insulation material layer 402′ and a mask material layer are sequentially formed on the base 400 along the third direction. In an example, a substrate of the base 400 may be a silicon substrate, a germanium substrate, a silicon germanium substrate, a silicon carbide substrate, a Silicon On Insulator (SOI) substrate, or a Germanium On Insulator (GOI) substrate, etc., may also be a substrate comprising other elemental semiconductors or compound semiconductors, such as a glass substrate or a group III-V compound substrate (such as a gallium nitride substrate, or a gallium arsenide substrate, etc.), may also be a structure of decks, such as Si/SiGe, etc., and may also be other epitaxial structures, such as an Silicon Germanium On Insulator (SGOI), etc.

In some examples, a process of forming the conductive material layer 401′, the insulation material layer 402′ and the mask material layer may include any process known in the art, including, but not limited to, chemical vapor deposition (CVD), physical vapor deposition (PVD), sputtering, and atomic layer deposition (ALD).

In some implementations, a material of the conductive material layer 401′ includes, but is not limited to, tungsten (W), cobalt (Co), copper (Cu), aluminum (Al), gold (Au), silver (Ag), nickel (Ni), and the like.

In some implementations, a material of the insulation material layer 402′ includes, but is not limited to, silicon nitride.

In some implementations, a material of the mask material layer includes one or more of photoresist (PR), silicon oxynitride (SiON) and hard mask (HM). In an example, as shown in FIG. 4, the mask material layer comprises a hard mask layer 403′, a silicon oxynitride material layer 404′ and a photoresist layer 405. The photoresist layer 405 has an opening.

In some examples, forming the plurality of conductive lines comprises: forming a conductive material layer and a patterned mask layer sequentially along the third direction, wherein the patterned mask layer comprises an insulation structure in contact with the conductive material layer; removing part of the conductive material layer by using the patterned mask layer, to form the plurality of conductive lines; and removing part of the patterned mask layer except the insulation structure, wherein the dimension of the insulation structure along the second direction is the same as the dimension of the conductive line along the second direction.

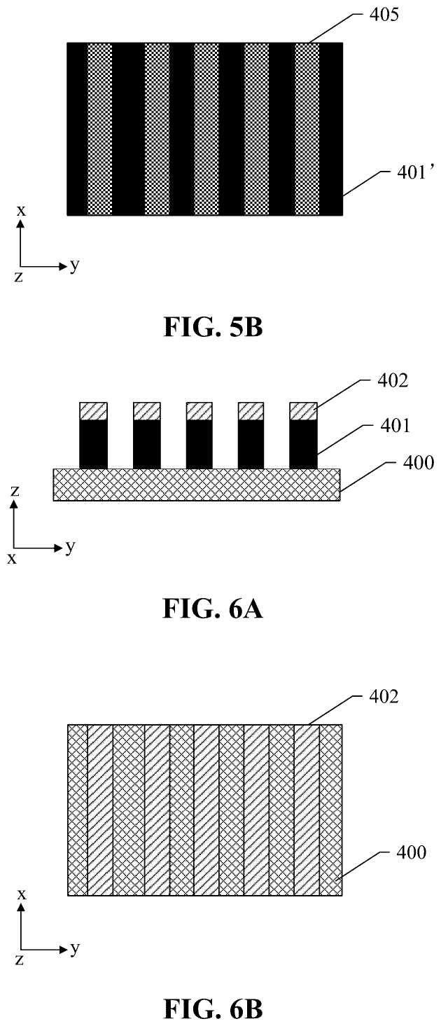

With reference to FIGS. 5A and 5B and in conjunction with FIG. 4, part of the insulation material layer 402′ and the mask material layer is removed along the third direction through the opening of the photoresist layer 405 to form the patterned mask layer 406. The patterned mask layer 406 comprises an insulation structure 402 in contact with the conductive material layer 401′, a hard mask 403, a silicon oxynitride layer 404 and the photoresist layer 405. The patterned mask layer 406 exposes part of a top surface of the conductive material layer 401′.

With reference to FIGS. 6A and 6B, by using the patterned mask layer, part of the conductive material layer is removed to form a plurality of conductive lines 401, wherein the plurality of conductive lines 401 extend along the first direction and are spaced apart along the second direction, and the first direction intersects the second direction; and part of the patterned mask layer except the insulation structure 402 is removed. Since the insulation structures 402 and the conductive lines 401 are formed through the same patterned mask layer, the insulation structures 402 extend along the first direction and are spaced apart along the second direction as well. In an example, the dimension of the insulation structure 402 along the second direction is the same as the dimension of the conductive line 401 along the second direction.

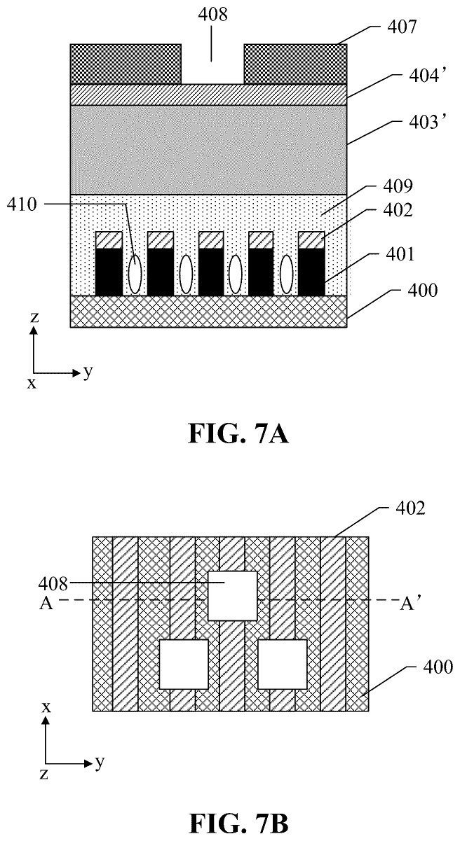

With reference to FIGS. 7a to 10E, S20 is performed to form the contact structure extending along the third direction and at least connected to the first conductive line of the plurality of conductive lines.

In some examples, forming the contact structure comprises: forming a dielectric layer at least covering the insulation structure; removing part of the dielectric layer and removing part of the insulation structure on the first conductive line to form a contact via; and filling a conductive material in the contact via to form the contact structure connected with the first conductive line.

With reference to FIGS. 7A and 7B, the dielectric layer 409 at least covering the insulation structure 402 is formed. In some implementations, a hard mask layer 403′, a silicon oxynitride material layer 404′ and a photoresist 407 are sequentially formed on the dielectric layer 409, wherein the photoresist 407 has an opening 408, and the dimension of the opening 408 in the second direction is greater than the dimension of the insulation structure 402 in the second direction.

It is to be noted that FIG. 7A is a schematic cross-sectional view along a direction of a cut line AA′ shown in FIG. 7B. For ease of a clear description of a positional relationship between the opening 408 and the insulation structure 402, FIG. 7B is a top view that only shows the opening 408, the insulation structure 402 and the base 400 since other structures in FIG. 7A are omitted.

In some examples, as shown in FIG. 7A, an air gap 410 is formed between two adjacent conductive lines to reduce capacitance between the conductive lines.

In some examples, as shown in FIGS. 7A and 7B, the opening 408 corresponding to the first conductive line is disposed in the photoresist above the first conductive line of the plurality of conductive lines 401.

In some examples, as shown in FIG. 7B, the openings 408 of the photoresist on the adjacent first conductive lines are staggered in the second direction.

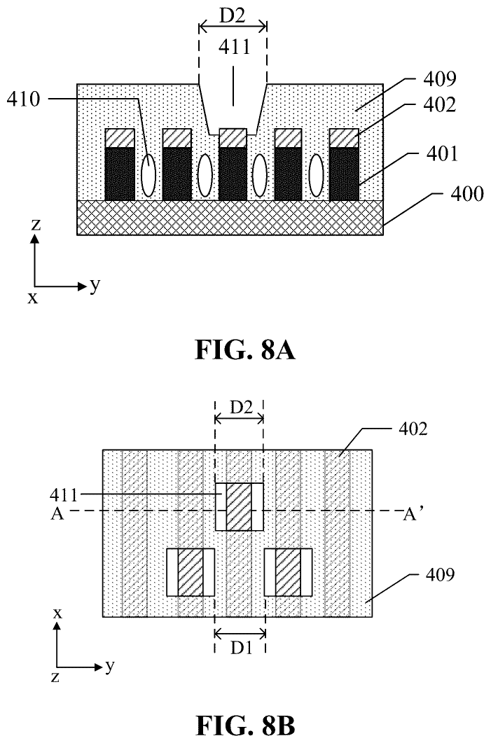

With reference to FIGS. 8A to 8B, in some examples, forming the contact via comprises: removing part of the dielectric layer 409 to form a first via 411, wherein a bottom of the first via 411 exposes a surface and part of a sidewall of the insulation structure 402 on the first conductive line away from the first conductive line; and a surface of the insulation structure 402 in contact with the conductive line 401 is lower than a bottom surface of the first via 411.

It is to be noted that FIG. 8A is a schematic cross-sectional view along a direction of a cut line AA′ shown in FIG. 8B. For ease of a clear description of a positional relationship between the opening 411 and the insulation structure 402, FIG. 8B is a top view that only shows the first via 411, the insulation structure 402 and the dielectric layer 409 since other structures in FIG. 8A are omitted, and the dielectric layer 409 is shown in an exposed view.

In some examples, as shown in FIG. 8B, forming the contact via further comprises: forming the first vias 411 staggered along the second direction on two adjacent first conductive lines respectively (not shown in FIG. 8B). As such, the problem of interconnection between the first vias 411 on the two adjacent first conductive lines, which results in a short circuit between the first conductive lines in a subsequent process, can be avoided in the second direction, such that the performance of the semiconductor device can be maintained.

In some examples, in the second direction, a distance between the first vias on the first conductive lines spaced apart is equal to the dimension of the first via. In some implementations, along the first/second direction, the dimension of the first via does not vary in the third direction.

In other implementations, since the first via 411 has a large aspect ratio, there is no sufficient etchant to reach the bottom during the process of forming the first via 411, and a decrease in reactant concentration will result in a reduction in a reaction rate of a bottom region of the first via 411. Therefore, when the dielectric layer 409 is etched from top to bottom, the formed first via 411 will have a shape of inverted trapezoid with a wide upper part and a narrow lower part. Thus, as shown in FIG. 8A, in the second direction, the dimension of the first via 411 varies along the third direction. In an example, the dimension of the first via 411 in the second direction gradually decreases from top to bottom, and the dimension D2 of the first via 411 in the second direction refers to the dimension of the top of the first via 411 in the second direction.

As shown in FIGS. 8A and 8B, in some examples, in the second direction, a distance D1 between the first vias 411 on the first conductive lines spaced apart is equal to the dimension D2 of the first via 411.

As such, the first via with a larger dimension can be formed to reduce contact resistance in a subsequent process, and the risk of short circuit in the subsequent process, which is caused by interconnection between the first vias on the first conductive lines spaced apart, can be avoided in the second direction.

In some examples, both D1 and D2 are in a range of 8 nm to 300 nm. In an example, D1 and D2 may be 8 nm, 50 nm, 100 nm, 150 nm, 200 nm, 250 nm or 300 nm.

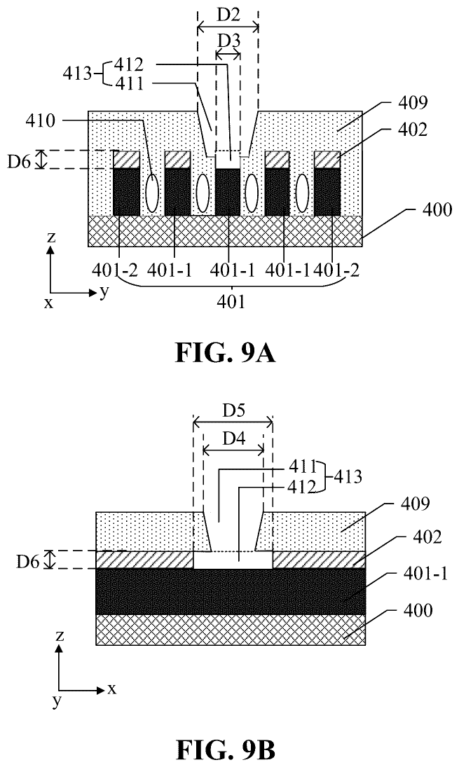

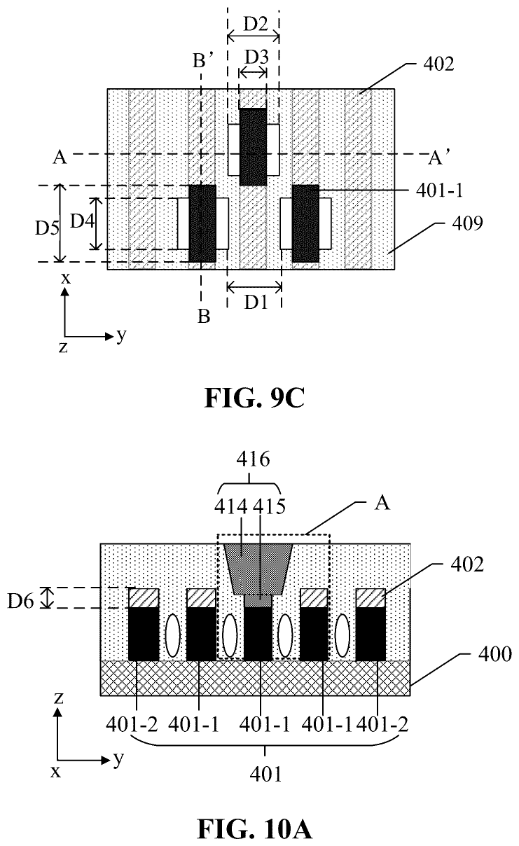

With reference to FIGS. 9A, 9B and 9C, in some examples, forming the contact via further comprises: removing part of the insulation structure 402 on at least the first conductive line 401-1 along the first via 411 by wet etching to form a second via 412, wherein a bottom of the second via 412 exposes a top surface of the first conductive line 401-1 of the plurality of the conductive lines 401; and the first via 411 and the second via 412 constitute a contact via 413.

It may be understood that one of the plurality of conductive lines 401 not exposed by the second via 412 is a second conductive line 401-2.

It is to be noted that FIG. 9A is a schematic cross-sectional view along a direction of a cut line AA′ shown in FIG. 9C, and FIG. 9B is a schematic cross-sectional view along a direction of a cut line BB′ shown in FIG. 9C. For ease of a clear description of a positional relationship between the first via 411 and the insulation structure 402, FIG. 9C is a top view that only shows the first via 411, the second via 412, the insulation structure 402, the conductive line and the dielectric layer 409 since other structures in FIG. 9A are omitted, and the dielectric layer 409 is shown in a an exposed view.

In the examples of the present disclosure, dashed lines in the contact via 413 as shown in FIGS. 9A and 9B are only used to distinguish the first via 411 and the second via 412 of the contact via 413, and it is to be emphasized that the dashed lines do not exist in an actual semiconductor device.

Since the second via 412 is formed at a position where part of the insulation structure 402 on the first conductive line 401-1 is removed, the second via 412 has the same morphology as the removed part of the insulation structure 402.

In some examples, with reference to FIGS. 9A to 9C, the dimension D3 of the second via 412 along the second direction is the same as the dimension of the conductive line (such as the first conductive line 401-1) along the second direction.

In some examples, as shown in FIGS. 9A and 9B, the dimension of the second via 412 along the third direction is the same as the dimension D6 of the insulation structure 402 in the third direction.

In some examples, the second via 412 formed by removing part of the insulation structure 402 by wet etching has a uniform and vertical sidewall; and as shown in FIGS. 9A and 9B, in the second direction, the dimension of the second via 412 does not vary along the third direction.

In some examples, in the first/second direction, the dimension of the first via does not vary along the third direction.

In some examples, in the second direction, the dimension of the second via is smaller than the dimension of the first via.

In some examples, in the first direction, the dimension of the second via is greater than the dimension of the first via.

In some examples, along the first/second direction, the dimension of the first via in the third direction varies, and in an example, the first via has a shape of inverted trapezoid with a wide upper part and a narrow lower part. It may be understood that the dimension of the first via in the first/second direction gradually decreases from top to bottom, and the dimension of the first via in the first/second direction refers to the dimension of the top of the first via.

As shown in FIGS. 9A and 9C, in some examples, in the second direction, the dimension D3 of the second via 412 is smaller than the dimension D2 of the first via 411.

In some examples, part of the insulation structure 402 on at least the first conductive line 401-1 is removed along the first via 411 by wet etching to form the second via 412. The etching solution of wet etching will be uniformly applied on material surfaces due to the isotropic characteristics of wet etching, i.e., the impact on the insulation structure 402 from the etching solution is uniform, and thus part of the insulation structure 402 in its extending direction (the first direction) will also be removed.

As shown in FIGS. 9B and 9C, in some examples, in the first direction, the dimension D5 of the second via 412 is greater than the dimension D4 of the first via 411.

As shown in FIGS. 9B and 9C, in some examples, in the first direction, half of a difference between the dimension D5 of the second via 412 and the dimension D4 of the first via 411 is equal to a height D6 of the insulation structure 402 along the third direction.

In some examples, the insulation structure 402 and the dielectric layer 409 have different etching rates. When removing part of the dielectric layer 409 to form the first vias 411, the insulation structure 402 can serve as a stop layer to control the depth of the first via 411.

In an example, a material of the insulation structure includes silicon nitride, and a material of the dielectric layer 409 includes Tetraethylorthosilicate (TEOS).

Moreover, since the insulation structure 402 has a certain thickness in the third direction, even if over etching occurs at the formed first via 411 as shown in FIG. 8A, the bottom surface of the first via 411 will still be higher than a bottom surface of the insulation structure 402 in contact with the conductive line 401, so that the conductive line 401 below the insulation structure 402 can be protected from damage, which can further prevent the air gap 410 between the adjacent conductive lines 401 from being damaged.

It is to be noted that, the thickness of the insulation structure in the third direction is greater than the over-etching depth of the dielectric layer, and the thickness of the insulation structure in the third direction can be set according to actual requirements.

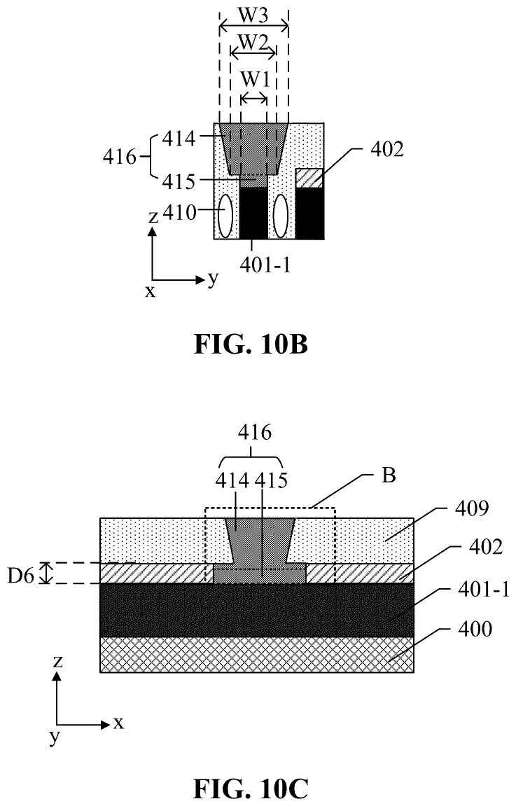

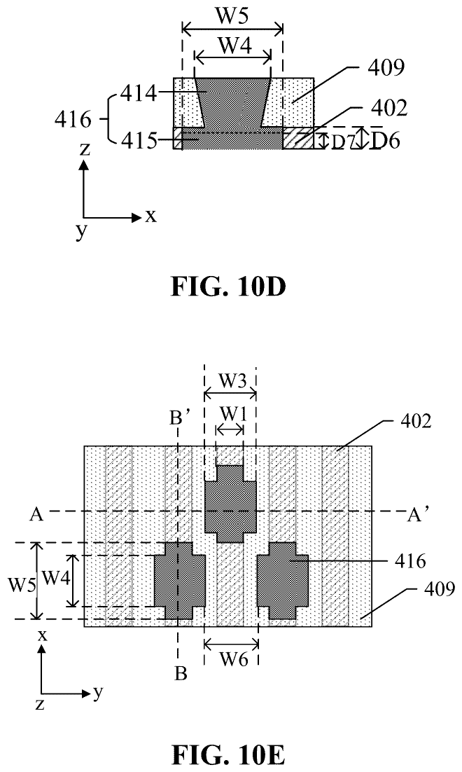

With reference to FIGS. 10A to 10E, forming the contact structure comprises: filling a conductive material in the contact via to form a contact structure 416 connected with the first conductive line 401-1.

It is to be noted that FIG. 10A is a schematic cross-sectional view along a direction of a cut line AA′ shown in FIG. 10E, FIG. 10C is a schematic cross-sectional view along a direction of a cut line BB′ shown in FIG. 10E, and FIG. 10B is an enlarged schematic view of a region A in FIG. 10A. FIG. 10D is an enlarged schematic view of a region B in FIG. 10C. For ease of a clear description of a positional relationship between the contact structure 416 and the insulation structure 402, FIG. 10E is a top view that only shows the contact structure 416, the insulation structure 402 and the dielectric layer 409 since other structures in FIG. 10A are omitted, and the dielectric layer 409 is shown in a an exposed view.

In some implementations, the conductive material includes, but is not limited to, tungsten (W), cobalt (Co), copper (Cu), aluminum (Al), gold (Au), silver (Ag), nickel (Ni), and the like.

In some examples, as shown in FIGS. 10A and 10B, the contact structure 416 comprises a first contact sub-structure 415 connected with the first conductive line 401-1 and a second contact sub-structure 414 located on the first contact sub-structure 415; and in the second direction, a first dimension W1 of the first contact sub-structure 415 at a boundary between the first contact sub-structure and the second contact sub-structure is smaller than a second dimension W2 of the second contact sub-structure 414 at the boundary between the first contact sub-structure and the second contact sub-structure.

In some implementations, in the second direction, the dimension of the second contact sub-structure does not vary in the third direction. In an example, in the second direction, the second dimension of the second contact sub-structure at the boundary between the first contact sub-structure and the second contact sub-structure is the same as the dimension of the top of the second contact sub-structure.

In other implementations, in the second direction, the second dimension W2 of the second contact sub-structure at the boundary between the first contact sub-structure and the second contact sub-structure is smaller than the dimension W3 of the top of the second contact sub-structure, as shown in FIGS. 10A and 10B.

It is to be noted that the first contact sub-structure 415 is formed in a first region of the second via 412 shown in FIGS. 9A and 9B, the second contact sub-structure 414 is formed in the first via 411 and a second region of the second via 412 shown in FIGS. 9A and 9B, and the first region and the second region together constitute the second via 412.

In some implementations, the dimension D7 of the first contact sub-structure 415 in the third direction is smaller than the dimension D6 of the insulation structure 402 in the third direction.

In the examples of the present disclosure, part of the insulation structure on the first conductive line is removed to reserve a position for forming the first contact sub-structure of the contact structure, and the first contact sub-structure of the contact structure is formed at the reserved position, such that the alignment accuracy between the contact structure and the first conductive line can be effectively improved, the problem of short circuit between the adjacent conductive lines due to an excessive deviation of the contact structure with respect to the first conductive line is avoided, and the contact resistance between the contact structure and the first conductive line is reduced. Furthermore, the air gap between the conductive lines is prevented from damage due to over-etching during the process of forming the contact structure, and the performance of the semiconductor device is improved.

Examples of the present disclosure further provide a semiconductor device. With reference to FIGS. 10A to 10E, the semiconductor device comprises: a plurality of conductive lines 401 extending along a first direction and spaced apart along a second direction, wherein the first direction intersects the second direction; and a contact structure 416 extending along a third direction and at least connected to a first conductive line 401-1 of the plurality of conductive lines 401, wherein the contact structure 416 comprises a first contact sub-structure 415 connected with the first conductive line 401-1 and a second contact sub-structure 414 located on the first contact sub-structure 415; and in the second direction, a first dimension W1 of the first contact sub-structure 415 at a boundary between the first contact sub-structure and the second contact sub-structure is smaller than a second dimension W2 of the second contact sub-structure 414 at the boundary between the first contact sub-structure and the second contact sub-structure, such that a contact area between the first contact sub-structure and the second contact sub-structure can be increased, and the contact resistance can be reduced, wherein the third direction is perpendicular to both the first direction and the second direction.

In some examples, the second contact sub-structure has a larger dimension than the first contact sub-structure, which is helpful to reduce the overall resistance of the contact structure.

In some examples, as shown in FIG. 10A, the semiconductor device further comprises a base 400. A plurality of conductive lines 401 are located on the base 400. In an example, a substrate of the base 400 may be a silicon substrate, a germanium substrate, a silicon germanium substrate, a silicon carbide substrate, a Silicon On Insulator substrate, or a Germanium On Insulator substrate, etc., may also be a substrate comprising other elemental semiconductors or compound semiconductors, such as a glass substrate or a group III-V compound substrate (such as a gallium nitride substrate, or a gallium arsenide substrate, etc.), may also be a structure of decks, such as Si/SiGe, etc., and may also be other epitaxial structures, such as an Silicon Germanium On Insulator (SGOI), etc.

It is to be noted that, in conjunction with FIGS. 10A and 10E, the contact structure is disposed on the first conductive line 401-1 of the plurality of conductive lines 401, no contact structure is disposed on a second conductive line 401-2 of the plurality of conductive lines 401, and both the first conductive line 401-1 and the second conductive line 401-2 can be referred to as the conductive lines. Since FIG. 10A is a schematic cross-sectional view along the direction of the cut line AA′ shown in FIG. 10E, only the contact structure 416 disposed on one first conductive line 401-1 is shown in FIG. 10A, and in fact, the contact structures 416 are also disposed on two adjacent first conductive lines 401-1.

As shown in FIG. 10B, in some examples, a ratio of the second dimension W2 to the first dimension W1 is in a range of 2-5. In an example, the ratio of the second dimension W2 to the first dimension W1 is 2, 3, 4 or 5.

As shown in FIGS. 10A to 10E, in some examples, the semiconductor device further comprises an insulation structure 402 located at a position on the plurality of conductive lines 401 other than the position where the contact structure 416 contacts the first conductive line 401-1. The dimension of the insulation structure 402 along the second direction is the same as the dimension of the conductive line 401 along the second direction; and a surface of the insulation structure 402 in contact with the conductive line 401 is flush with a surface of the first contact sub-structure 415 in contact with the first conductive line 401-1.

In some examples, the second via is formed by removing part of the insulation structure 402 on the first conductive line 401-1, the first contact sub-structure 415 is formed in a part of the second via, and a dimension of the first contact sub-structure 415 along the second direction is the same as the dimension of the insulation structure 402 along the second direction.

Since the insulation structure 402 and the conductive line 401 are formed through the same patterned mask layer, the dimension of the insulation structure 402 along the second direction is the same as the dimension of the conductive line 401 along the second direction. In some examples, as shown in FIG. 10E, an orthographic projection of the insulation structure 402 on a surface of the base overlaps with an orthographic projection of the second conductive line 401-2 (not shown in FIG. 10E) on the surface of the base.

Further, as shown in FIGS. 10A and 10B, in some examples, the dimension W1 of the first contact sub-structure 415 along the second direction is the same as the dimension of the conductive line 401 (the first conductive line 401-1) along the second direction.

By reserving the position, the dimension of the first contact sub-structure is the same as the dimension of the first conductive line along the second direction, such that the alignment accuracy between the contact structure and the first conductive line can be effectively improved, and the problem of short circuit between the adjacent conductive lines due to an excessive deviation of the contact structure with respect to the first conductive line can be avoided. At the same time, the contact resistance between the contact structure and the first conductive line is reduced, and the performance of the semiconductor device is improved.

In some examples, in the second direction, a dimension of the first contact sub-structure does not vary along the third direction, and the dimension of the second contact sub-structure does not vary along the third direction.

In other examples, as shown in FIGS. 10A and 10B, in some examples, in the second direction, a dimension of the first contact sub-structure 415 does not vary along the third direction, the dimension of the second contact sub-structure 414 varies along the third direction, the dimension of the second contact sub-structure 414 along the third direction decreases from top to bottom, and the dimension W3 of the second contact sub-structure 414 in the second direction refers to the dimension of the top of the second contact sub-structure.

As shown in FIGS. 10D and 10E, in some examples, in the first direction, a third dimension W5 of the first contact sub-structure 415 is greater than a fourth dimension W4 of the second contact sub-structure. The fourth dimension W4 of the second contact sub-structure refers to the dimension of the top of the second contact sub-structure in the first direction.

As shown in FIGS. 10D and 10E, in some examples, half of a difference between the third dimension W5 and the fourth dimension W4 is greater than the dimension D7 of the first contact sub-structure 415 along the third direction.

In some examples, a cross section of the second contact sub-structure 414 perpendicular to the third direction comprises any one of a circle, an ellipse or a square.

In some examples, a surface of the insulation structure 402 away from the conductive line 401 is higher than a surface of the first contact sub-structure 415 away from the first conductive line 401-1.

In some examples, in the first direction, half of a difference between the third dimension W5 of the first contact sub-structure 415 and the fourth dimension W4 of the second contact sub-structure 414 is the same as the dimension of the insulation structure 402 along the third direction.

As shown in FIG. 10D, in some examples, a ratio of the dimension D6 of the insulation structure 402 along the third direction to the dimension D7 of the first contact sub-structure 415 along the third direction is in a range of 1.5-5. In an example, the ratio of the dimension D6 of the insulation structure 402 along the third direction to the dimension D7 of the first contact sub-structure 415 along the third direction is 1.5, 2, 2.5, 3, 3.5, 4, 4.5 or 5.

Since the insulation structure 402 has a certain thickness in the third direction, the insulation structure 402 can prevent over-etching during the formation of the contact structure. A bottom surface of the second contact sub-structure 414 is higher than a bottom surface of the insulation structure 402 in contact with the conductive line 401, and a top surface (a surface of the insulation structure 402 away from the conductive line 401) of the insulation structure 402 is higher than a top surface (a surface of the first contact sub-structure 415 away from the first conductive line 401-1) of the first contact sub-structure 415. Therefore, the conductive line 401 below the insulation structure 402 can be protected from damage.

In some examples, a material of the insulation structure 402 includes silicon nitride, and the dimension D6 of the insulation structure 402 along the third direction is in a range of 40 nm-60 nm. In an example, the dimension D6 of the insulation structure 402 along the third direction is 40 nm, 50 nm or 60 nm.

In some examples, as shown in FIGS. 10A and 10B, an air gap 410 is disposed between two adjacent ones of the conductive lines 401 to reduce the capacitance between the conductive lines 401.

In some examples, as shown in FIG. 10B, a top surface of the air gap 410 is not higher than a top surface of the conductive line 401. Since the surface of the insulation structure 402 in contact with the conductive line 401 is flush with the surface of the first contact sub-structure 415 in contact with the first conductive line 401-1, and the top surface of the air gap 410 is not higher than the top surface of the conductive line 401, the first contact sub-structure 415 will not damage the air gap 410, thereby improving the performance of the semiconductor device.

In some examples, as shown in FIG. 10B, a ratio of a distance between the adjacent conductive lines 401 to the dimension of the air gap 410 along the second direction is in a range of 1.5-2.5. In an example, the ratio of the distance between the adjacent conductive lines 401 to the dimension of the air gap 410 along the second direction is 1.5, 2 or 2.5. The dimension of the air gap is set properly according to the distance between the adjacent conductive lines, so that the capacitance between the conductive lines can be minimized.

In some examples, the second contact sub-structures of the contact structures on adjacent ones of the first conductive lines are staggered in the second direction. In an example, as shown in FIG. 10E, the second contact sub-structures of the contact structures on adjacent ones of the first conductive lines 401-1 are staggered in the second direction. As such, the problem of short circuit between the first conductive lines, which is caused by interconnection between the second contact sub-structures on two adjacent first conductive lines, can be avoided in the second direction.

In some examples, in the second direction, a distance between the second contact sub-structures of the contact structures on the first conductive lines spaced apart is equal to a dimension of the second contact sub-structure. In an example, as shown in FIG. 10E, in the second direction, a distance W6 between the second contact sub-structures of the contact structures 416 on the first conductive lines 401-1 spaced apart is equal to the dimension W3 of the second contact sub-structure.

It is to be noted that, in the second direction, the dimension W3 of the second contact sub-structure refers to the dimension of the top of the second contact sub-structure along the third direction.

As such, the second contact sub-structure with a larger dimension can be formed to reduce the contact resistance, and the risk of short circuit, which is caused by interconnection between the second contact sub-structures on the first conductive lines spaced apart, can be avoided in the second direction.

In other examples, as shown in FIGS. 10A and 10B, in the second direction, the dimension of the second contact sub-structure 414 along the third direction decreases from top to bottom, i.e., the dimension W3 of the second contact sub-structure 414 in the second direction is the maximum dimension of the second contact sub-structure.

In some examples, the dimension of the second contact sub-structure 414 in the second direction is in a range of 8 nm-300 nm. In an example, the dimension of the second contact sub-structure 414 in the second direction is 8 nm, 100 nm, 150 nm, 200 nm, 250 nm or 300 nm.

In some examples, the conductive line comprises at least one of a bit line, a word line or an interconnect line.

In some examples, the semiconductor device further comprises a memory array structure and a peripheral structure connected with the memory array structure, wherein the interconnect line is located at a connection of the memory array structure and the peripheral structure. In some implementations, the semiconductor device may be a memory or part of the memory. The memory includes, but is not limited to, a NAND memory.

According to the semiconductor device provided in the examples of the present disclosure, part of the insulation structure on the first conductive line of the conductive lines is removed to reserve a position for forming the first contact sub-structure of the contact structure, and in the second direction, the first dimension of the first contact sub-structure at the boundary between the first contact sub-structure and the second contact sub-structure is smaller than the second dimension of the second contact sub-structure at the boundary between the first contact sub-structure and the second contact sub-structure, such that alignment accuracy between the contact structure and the first conductive line can be effectively improved, contact resistance between the contact structure and the first conductive line is reduced, and overall resistance of the contact structure is reduced. Furthermore, the air gap between the conductive lines can be prevented from damage due to over-etching during the formation of the contact structure, and the performance of the semiconductor device is improved.

According to a third aspect of the examples of the present disclosure, a memory system is provided, comprising: at least one semiconductor device of the aforementioned examples; and a controller configured to control the semiconductor device.

Here, the semiconductor device may be a memory, or part of the memory. A detailed description is made below by taking the semiconductor device being a memory as an example.

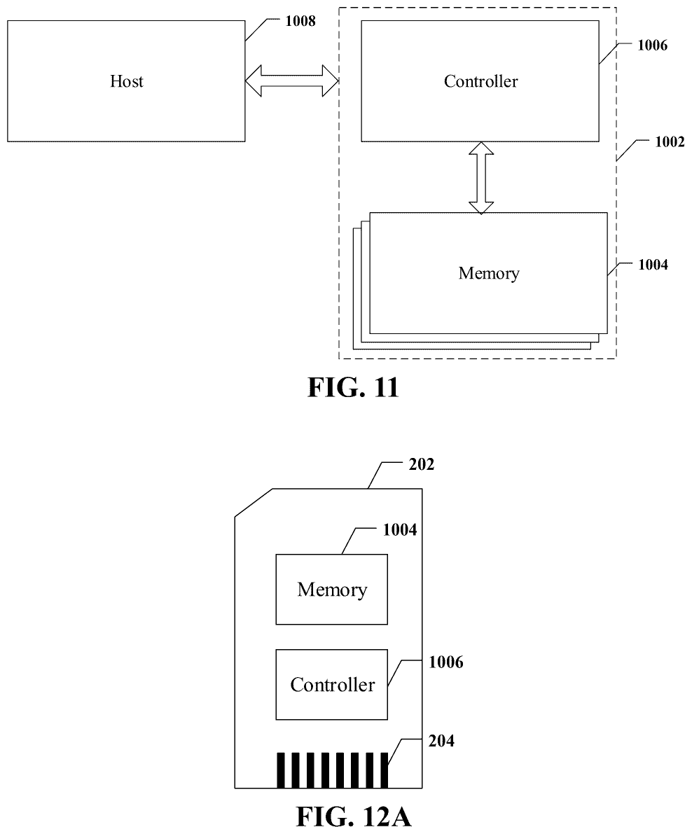

FIG. 11 shows a block diagram of an example system 1000 having a memory according to some aspects of the present disclosure. The system 1000 may be a mobile phone, a desktop computer, a laptop computer, a tablet computer, a vehicle computer, a gaming console, a printer, a positioning apparatus, a wearable electronic apparatus, a smart sensor, a Virtual Reality (VR) apparatus, an Augmented Reality (AR) apparatus, or any other suitable electronic apparatuses having memories therein. As shown in FIG. 11, the system 1000 may comprise a host 1008 and a memory system 1002. The memory system 1002 has one or more memories 1004 and a controller 1006. The host 1008 may be a processor of an electronic apparatus (e.g., a central processing unit (CPU)) or a system on chip (SoC) (e.g., an Application Processor (AP)). The host 1008 may be configured to send or receive data to or from the memory 1004.

According to some implementations, the controller 1006 is coupled to the memory 1004 and the host 1008, and is configured to control the memory 1004. The controller 1006 can manage data stored in the memory 1004 and communicate with the host 1008. In some implementations, the controller 1006 is designed for operating in a low duty-cycle environment, such as a Secure Digital (SD) card, a Compact Flash (CF) card, a Universal Serial

Bus (USB) flash drive, or other media for use in electronic apparatuses, such as a personal computer, a digital camera, and a mobile phone, etc.

In some implementations, the controller 1006 is designed for operating in a high duty-cycle environment, such as a Solid State Disk (SSD) or an embedded Multi Media Card (eMMC) which is used as a data memory for a mobile apparatus, such as a smartphone, a tablet computer, and a laptop computer, etc., and an enterprise memory array.

The controller 1006 may be configured to control operations of the memory 1004, such as read, erase, and program operations. The controller 1006 may be further configured to manage various functions with respect to data stored or to be stored in the memory 1004, including, but not limited to, bad-block management, garbage collection, logical-to-physical address conversion, wear leveling, etc. In some implementations, the controller 1006 is further configured to process error correction codes (ECC) with respect to the data read from or written to the memory 1004.

The controller 1006 may further perform any other suitable functions, for example, formatting the memory 1004. The controller 1006 may communicate with an external apparatus (e.g., the host 1008) according to a specific communication protocol. For example, the controller 1006 may communicate with the external apparatus through at least one of various interface protocols, such as a USB protocol, an MMC protocol, a Peripheral Component Interconnection (PCI) protocol, a PCI Express (PCI-E) protocol, an Advanced Technology Attachment (ATA) protocol, a Serial ATA protocol, a Parallel ATA protocol, a Small Computer Small Interface (SCSI) protocol, an Enhanced Small Disk Interface (ESDI) protocol, an Integrated Drive Electronics (IDE) protocol, and a Firewire protocol, etc.

The controller 1006 and one or more memories 1004 may be integrated into various types of storage apparatuses, for example, be comprised in the same package (such as a universal flash storage (UFS) package or an eMMC package). That is to say, the memory system 1002 may be implemented and packaged into different types of end electronic products.

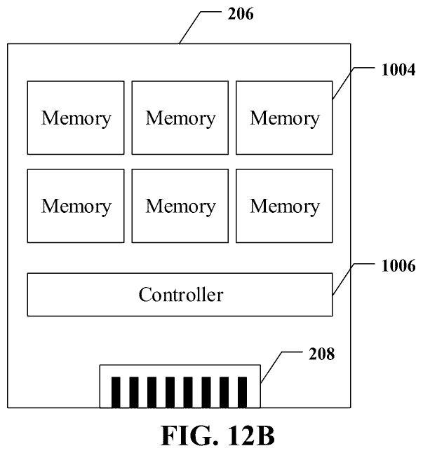

In an example as shown in FIG. 12A, the controller 1006 and a single memory 1004 may be integrated into a memory card 202. The memory card 202 may comprise a PC card (Personal Computer Memory Card International Association (PCMCIA)), a CF card, a Smart Media (SM) card, a memory stick, a multimedia card (MMC, RS-MMC, MMCmicro), an SD card (SD, miniSD, microSD, SDHC), and a UFS, etc. The memory card 202 may further comprise a memory card connector 204 coupling the memory card 202 with a host (e.g., the host 1008 in FIG. 11).

In another example as shown in FIG. 12B, the controller 1006 and a plurality of memories 1004 may be integrated into an SSD 206. The SSD 206 may further comprise an SSD connector 208 coupling the SSD 206 with a host (e.g., the host 1008 in FIG. 11). In some implementations, the storage capacity and/or the operation speed of the SSD 206 is greater than those of the memory card 202.

It is to be understood that references to “an example” or “some examples” throughout this specification mean that specific features, structures, or characteristics related to the example or examples are comprised in at least one example of the present disclosure. Therefore, “in an example” or “in some examples” presented throughout this specification does not necessarily refer to the same example. In addition, these specific features, structures or characteristics may be incorporated in one or more examples in any proper manner. It is to be understood that, in various examples of the present disclosure, the sequence number of each process above does not indicate the execution sequence. The execution sequence of each process should be determined by its functions and inherent logic, and should not constitute any limitation on the implementation process of examples of the present disclosure. The above sequence numbers of the examples of the present disclosure are only for description, and do not represent advantages and disadvantages of the examples.

The above descriptions are merely specific implementations of the present disclosure, and the protection scope of the present disclosure is not limited thereto. Any variation or replacement that may be readily figured out by those skilled in the art within the technical scope disclosed by the present disclosure shall fall within the protection scope of the present disclosure.

What is claimed is:

1. A semiconductor device, comprising:
a plurality of conductive lines extending along a first direction and spaced apart along a second direction, wherein the first direction intersects the second direction; and
a contact structure extending along a third direction and at least connected to a first conductive line of the plurality of conductive lines, wherein the contact structure comprises a first contact sub-structure connected with the first conductive line and a second contact sub-structure located on the first contact sub-structure; and in the second direction, a first dimension of the first contact sub-structure at a boundary between the first contact sub-structure and the second contact sub-structure is smaller than a second dimension of the second contact sub-structure at the boundary between the first contact sub-structure and the second contact sub-structure, wherein the third direction is perpendicular to both the first direction and the second direction.

2. The semiconductor device of claim 1, wherein a dimension of the first contact sub-structure along the second direction is same as a dimension of the first conductive line along the second direction.

3. The semiconductor device of claim 1, wherein in the second direction, a dimension of the first contact sub-structure does not vary along the third direction, and a dimension of the second contact sub-structure varies along the third direction.

4. The semiconductor device of claim 1, wherein in the first direction, a third dimension of the first contact sub-structure is greater than a fourth dimension of the second contact sub-structure.

5. The semiconductor device of claim 4, wherein half of a difference between the third dimension and the fourth dimension is greater than a dimension of the first contact sub-structure along the third direction.

6. The semiconductor device of claim 1, further comprising:
an insulation structure located at a position on the plurality of conductive lines other than a position where the contact structure contacts the first conductive line, wherein a dimension of the insulation structure along the second direction is same as a dimension of a conductive line along the second direction; and a surface of the insulation structure in contact with the conductive line along the second direction is flush with a surface of the first contact sub-structure in contact with the first conductive line.

7. The semiconductor device of claim 6, wherein a surface of the insulation structure away from the conductive line along the second direction is higher than a surface of the first contact sub-structure away from the first conductive line.

8. The semiconductor device of claim 1, wherein an air gap is disposed between two adjacent conductive lines.

9. The semiconductor device of claim 8, wherein a top surface of the air gap is not higher than top surfaces of the conductive lines.

10. The semiconductor device of claim 1, wherein second contact sub-structures of contact structures on adjacent first conductive lines are staggered in the second direction.

11. The semiconductor device of claim 10, wherein in the second direction, a distance between the second contact sub-structures of the contact structures on first conductive lines spaced apart is equal to a dimension of the second contact sub-structure.

12. The semiconductor device of claim 1, wherein the plurality of conductive lines comprise at least one of a bit line, a word line or an interconnect line, wherein the semiconductor device further comprises a memory array structure and a peripheral structure connected with the memory array structure, and wherein the interconnect line is located at a connection of the memory array structure and the peripheral structure.

13. A memory system, comprising:
at least one semiconductor device comprising:
a plurality of conductive lines extending along a first direction and spaced apart along a second direction, wherein the first direction intersects the second direction; and
a contact structure extending along a third direction and at least connected to a first conductive line of the plurality of conductive lines, wherein the contact structure comprises a first contact sub-structure connected with the first conductive line and a second contact sub-structure located on the first contact sub-structure; and in the second direction, a first dimension of the first contact sub-structure at a boundary between the first contact sub-structure and the second contact sub-structure is smaller than a second dimension of the second contact sub-structure at the boundary between the first contact sub-structure and the second contact sub-structure, wherein the third direction is perpendicular to both the first direction and the second direction; and
a controller configured to control the semiconductor device.

14. A formation method of a semiconductor device, comprising:
forming a plurality of conductive lines, wherein the plurality of conductive lines extend along a first direction and are spaced apart along a second direction, and the first direction intersects the second direction; and
forming a contact structure extending along a third direction and at least connected to a first conductive line of the plurality of conductive lines, wherein the contact structure comprises a first contact sub-structure connected with the first conductive line and a second contact sub-structure located on the first contact sub-structure; and in the second direction, a first dimension of the first contact sub-structure at a boundary between the first contact sub-structure and the second contact sub-structure is smaller than a second dimension of the second contact sub-structure at the boundary between the first contact sub-structure and the second contact sub-structure, wherein the third direction is perpendicular to both the first direction and the second direction.

15. The formation method of claim 14, wherein forming the plurality of conductive lines comprises:
forming a conductive material layer and a patterned mask layer sequentially along the third direction, wherein the patterned mask layer comprises an insulation structure in contact with the conductive material layer;
removing part of the conductive material layer by using the patterned mask layer, to form the plurality of conductive lines; and
removing part of the patterned mask layer except the insulation structure, wherein a dimension of the insulation structure along the second direction is same as a dimension of the conductive line along the second direction.

16. The formation method of claim 15, wherein forming the contact structure comprises:
forming a dielectric layer at least covering the insulation structure;
removing part of the dielectric layer and removing part of the insulation structure on the first conductive line to form a contact via; and
filling a conductive material in the contact via to form the contact structure connected with the first conductive line.

17. The formation method of claim 16, wherein forming the contact via comprises:
removing part of the dielectric layer to form a first via, wherein a bottom of the first via exposes a surface and part of a sidewall of the insulation structure on the first conductive line away from the first conductive line; and a surface of the insulation structure in contact with the first conductive line is lower than a bottom surface of the first via; and
removing part of the insulation structure on at least the first conductive line along the first via by wet etching to form a second via, wherein a bottom of the second via exposes a top surface of the first conductive line; and the first via and the second via constitute the contact via.

18. The formation method of claim 17, further comprising:
forming first vias staggered along the second direction on two adjacent first conductive lines respectively, wherein in the second direction, a distance between the first vias on first conductive lines spaced apart is equal to a dimension of the first via.

19. The formation method of claim 17, wherein a dimension of the second via along the second direction is same as the dimension of a conductive line along the second direction, and wherein in the second direction, a dimension of the second via does not vary along the third direction, and a dimension of the first via varies along the third direction.

20. The formation method of claim 17, wherein in the second direction, a dimension of the second via is smaller than a dimension of the first via, and wherein in the first direction, a dimension of the second via is greater than a dimension of the first via.
